(19) United States
(12) Patent Application Publication
(10) Pub. No.: US 2016/0276212 A1
(43) Pub. Date: Sep. 22, 2016

(54) Method For Producing Semiconductor Device

(71) Applicant: Renesas Electronics Corporation, Tokyo (JP)

(72) Inventor: Kotaro HORIKOSHI, Ibaraki (JP)

(21) Appl. No.: 15/005,267

(22) Filed: Jan. 25, 2016

(30) Foreign Application Priority Data
Mar. 20, 2015 (JP) 2015-058032

(51) Int. Cl. H01L 21/768; H01L 23/532; H01L 21/02; H01L 21/027; H01L 21/311

(52) U.S. Cl. CPC H01L 21/76802; H01L 21/0274; H01L 21/31116; H01L 21/02164; H01L 21/31144; H01L 23/53228

(57) ABSTRACT

A semiconductor device is produced while keeping a short circuit margin between its interconnects. A method therefor includes a step in which when a multilayered resist is used to make an interconnect trench in an interlayer dielectric, a mixed gas including, as components thereof, at least CF₄ gas, C₃H₂F₄ gas and O₂ gas is used to perform dry etching in order to form the multilayered resist.

### CROSS-REFERENCE TO RELATED APPLICATIONS

The disclosure of Japanese Patent Application No. 2015-058032 filed on Mar. 20, 2015 including the specification, drawings and abstract is incorporated herein by reference in its entirety.

### BACKGROUND

The present invention relates to a method for producing a semiconductor device, particularly, a method for producing a semiconductor device, using a multilayered resist.

In a process for producing a semiconductor product such as an advanced microcomputer, an advanced SOC (system-on-a-chip) product or a highly functional liquid crystal driver, there is used ArF photolithography using an ArF excimer laser, or a damascene process, in which an interconnect layer is formed to be buried in an insulating film.

When trenches (interconnect trenches) are made in an insulating film in a damascene process, the following is used as an etching mask: a multilayered resist obtained by stacking some of a photoresist film, inorganic thin films such as a bottom-anti-reflection film (BARC (bottom-anti-reflection-coating) film and an SOG (spin-on-glass) film, and organic films such as a TEOS (tetraethoxysilane) film onto each other.

In a process using this multilayered resist, a desired interconnect pattern is transferred onto a photoresist film as a topmost layer through ArF lithography, and then the photoresist film is used as an etching mask to etch a BARC film, an SOG film and a TEOS film successively. Lastly, an insulating film positioned below the multilayered resist is etched to make interconnect trenches (trenches) in the insulating film.

As a background technique in the present technical field, a technique as disclosed in Japanese Unexamined Patent Application Publication No. 2001-274141 is known. Japanese Unexamined Patent Application Publication No. 2001-274141 discloses a method for producing a semiconductor device, including the step of etching an insulating film made of a silicon based material with a mixed gas of CHF₃, CO and CF₄.

Japanese Unexamined Patent Application Publication No. 2005-311350 and Japanese Unexamined Patent Application Publication No. 2007-3354450 each disclose a method for producing a semiconductor device, using a multilayered resist.

Japanese Unexamined Patent Application Publication No. 2011-119310 discloses a method of etching a thin film made of a semiconductor, dielectric material or metal with an etching gas containing CHF₂COF.

Japanese Unexamined Patent Application Publication No. 2013-30531 discloses a dry etchant containing CₐF_{b}H_{c} in which a, b and c each represent a positive integer and satisfy relationships of 2≦a≦5, c<b≧1, 2>a+2>b+c, and b≦a+c provided that a case where a is 3, b is 4 and c is 2 is excluded.

As described above, when a multilayered resist including an SOG film and a TEOS film is used, an etching gas including CF₄ gas is used to etch the SOG film and the TEOS film. Thus, side etch is easily generated in the SOG film and the TEOS film so that the resultant semiconductor product is decreased in short circuit margin between its interconnects. As a result, in a process of producing such semiconductor products, the products are lowered in production yield and reliability.

Other problems, and novel features of the present invention will be made evident from the description of the present specification and drawings attached thereto.

### SUMMARY

An aspect of the present invention is a method for producing a semiconductor device including a step in which when a multilayered resist is used to make an interconnect trench in an interlayer dielectric, a mixed gas including, as components thereof, at least CF₄ gas, C₃H₂F₄ gas and O₂ gas is used to perform dry etching in order to form the multilayered resist.

The aspect makes it possible that in a process of producing semiconductor products, the products are restrained from being lowered in production yield and reliability, in particular, that semiconductor devices high in performance are produced while each keeping a short circuit margin between their interconnects.

### BRIEF DESCRIPTION OF THE DRAWINGS

FIG. 1A is a partial sectional view illustrating a workpiece in a process for producing a semiconductor device.

FIG. 1B is a partial sectional view illustrating a workpiece obtained by etching the workpiece in FIG. 1A in the process.

FIG. 2A is a partial sectional view illustrating a workpiece in a step in a process according to an embodiment of the present invention for producing a semiconductor device.

FIG. 2B is a partial sectional view illustrating a workpiece obtained by etching the workpiece in FIG. 2A in the process.

FIG. 3A is a partial sectional view illustrating the workpiece in a subsequent step in the process.

FIG. 3B is a partial sectional view illustrating a workpiece obtained by etching the workpiece in FIG. 3A in the process.

FIG. 4A is a partial sectional view illustrating a step in a semiconductor producing process according to the embodiment of the present invention.

FIG. 4B is a partial sectional view illustrating a step after the just-above-described step in the process.

FIG. 4C is a partial sectional view illustrating a step after the just-above-described step in the process.

FIG. 4D is a partial sectional view illustrating a step after the just-above-described step in the process.

FIG. 4E is a partial sectional view illustrating a step after the just-above-described step in the process.

FIG. 4F is a partial sectional view illustrating a step after the just-above-described step in the process.

FIG. 4G is a partial sectional view illustrating a step after the just-above-described step in the process.

FIG. 5A is a partial sectional view illustrating a step in a semiconductor producing process according to another embodiment of the present invention.

FIG. 5B is a partial sectional view illustrating a step after the just-above-described step in the process.

FIG. 5C is a partial sectional view illustrating a step after the just-above-described step in the process.

FIG. 5D is a partial sectional view illustrating a step after the just-above-described step in the process.

FIG. 5E is a partial sectional view illustrating a step after the just-above-described step in the process.

FIG. 5F is a partial sectional view illustrating a step after the just-above-described step in the process.

FIG. 5G is a partial sectional view illustrating a step after the just-above-described step in the process.

FIG. 6A is a view that schematically illustrates a reaction of a resist surface in a dry etching.

FIG. 6B is a view that schematically illustrates a reaction of a resist surface in another dry etching.

FIG. 7 is a view that schematically illustrates a dry etching apparatus.

FIG. 8 is a flow chart showing an outline of a process for producing a semiconductor device.

FIG. 9 is a flow chart showing an outline of a previous process of the semiconductor device producing process.

### DETAILED DESCRIPTION

Hereinafter, examples of the present invention will be described with reference to the drawings. Between the individual drawings, the same reference number is attached to the same constituents or parts. About the same constituents or parts, detailed overlapped descriptions thereabout will be omitted.

### First Embodiment

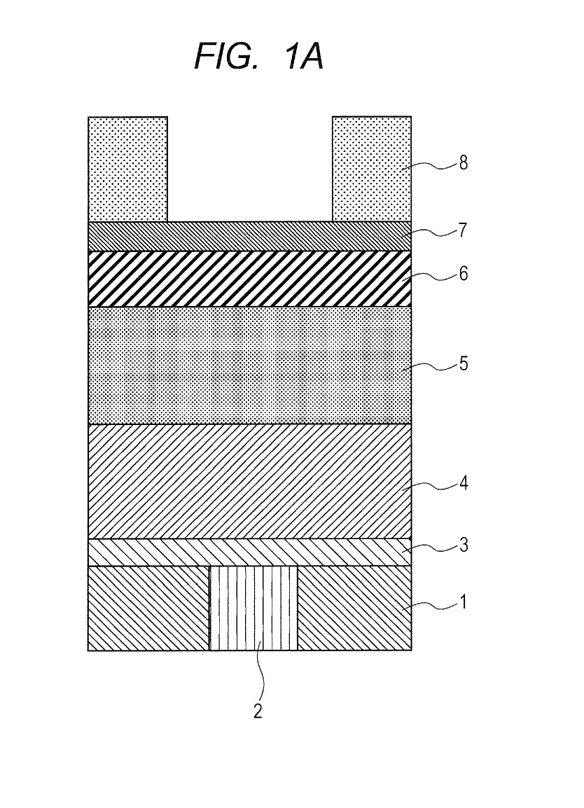

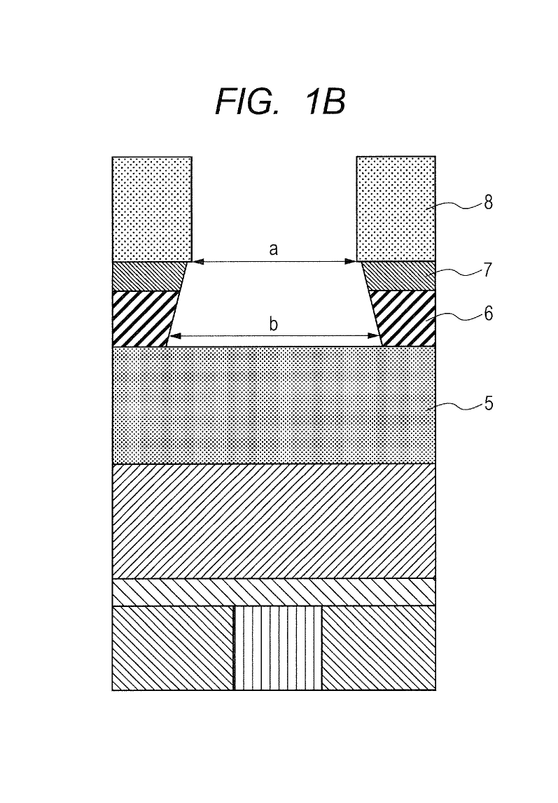

Referring to FIGS. 1A and 1B, a description will be made about a method for working trenches (interconnect trenches) in a single damascene process using a multilayered resist. FIG. 1A illustrates a state of a bottom-anti-reflection film (BARC film) and an intermediate layer (TEOS film) each formed over a surface of a semiconductor wafer before the two members are etched, and FIG. 1B illustrates a state of the bottom-anti-reflection film (BARC film) and the intermediate layer (TEOS film) after the etching.

As illustrated in FIG. 1A, a silicon oxide film 1 is formed on the surface (main surface) of the semiconductor wafer before the etching. Tungsten plugs including a tungsten plug 2, and lower-layer interconnects not illustrated are formed in portions of the film 1. A barrier film (SiCN film) 3 is formed as an insulating film on the silicon oxide film 1. The barrier film (SiCN film) 3 functions as an etching stopper film when each trench (interconnect trench) is worked.

On the barrier film (SiCN film) 3, for example, a silicon oxide film 4 is formed as an insulating film which is a working-receiving film in which trenches (interconnect trenches) are to be made. A multilayered resist is formed on the silicon oxide film 4. This multilayered resist is made of four layers in which from the bottom of this resist, the following are successively arranged: a lower-layer resist film 5, the intermediate layer (TEOS film) referred to above, which is a silicon oxide film 6, the bottom-anti-reflection film referred to above, which is a BARC film 7 functioning as an anti-reflection film when the workpiece illustrated in FIG. 1A is exposed to light, and a photoresist film 8. The silicon oxide film (TEOS film) 6 is an example of an insulating film. The insulating film may be a film of a different material.

The photoresist film 8 is an ArF resist photosensitized by ArF exposure using an ArF laser. In the photoresist film 8, a predetermined pattern for, for example, an interconnect pattern or circuit pattern of a semiconductor device is formed through a photolithography using an ArF exposure apparatus.

As attained in the stacked film structure illustrated in FIG. 1A, in the single damascene trench (interconnect trench) working using the multilayered resist as the mask, the BARC film 7, the TEOS film 6 as the intermediate film, and the lower-layer resist film 5 are successively etched with tetrafluoromethane (CF₄) gas, a mixed gas of argon (Ar) and tetrafluoromethane (CF₄), and a mixed gas of nitrogen (N₂) and oxygen (O₂), respectively.

Thereafter, the silicon oxide film 4, in which the trenches (interconnect trenches) are to be made, is etched with a mixed gas of argon (Ar) and tetrafluoromethane (CF₄). Thereafter, the workpiece is subjected to asking with oxygen (O₂) gas, and the barrier film (SiCN film) 3 is etched with a mixed gas of argon (Ar), tetrafluoromethane (CF₄) gas and oxygen (O₂) to end the etching.

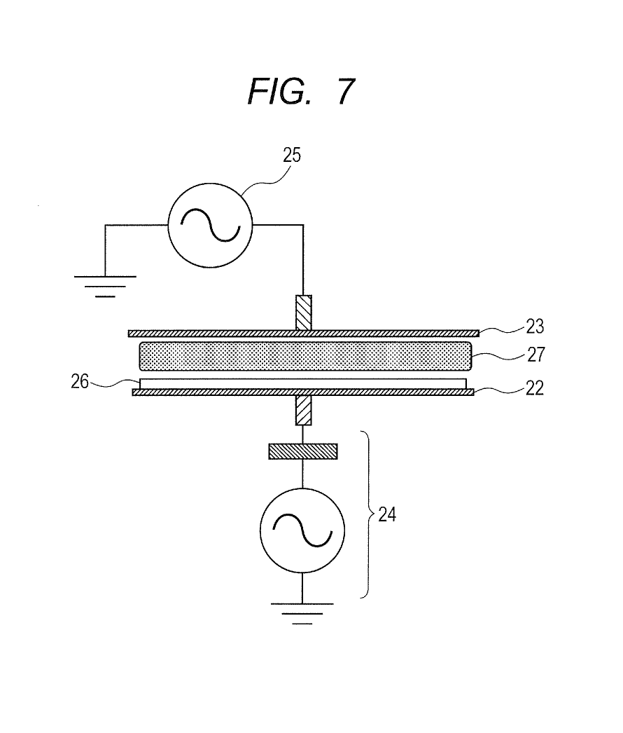

As an apparatus for the etching, a dry etching apparatus as illustrated in FIG. 7 is used, which is of a two-frequency will be lowered parallel plate type. A lower electrode 22 of the dry etching apparatus illustrated in FIG. 7 functions as a wafer stage, and a semiconductor wafer 26 is put thereon. An upper electrode 23 is arranged in parallel to the lower electrode 22 to have a predetermined interval between these electrodes 22 and 23.

A high-frequency power source A24 is electrically coupled to the lower electrode 22. A high-frequency electric power of 2 MHz is applied to the lower electrode 22.

A high-frequency power source B25 is electrically coupled to the upper electrode 23. A high-frequency electric power of 60 MHz is applied to the upper electrode 23.

The lower electrode 22, the semiconductor wafer 26, and the upper electrode 23 are set inside a processing chamber of the dry etching apparatus. The processing chamber is vacuum-evacuated, and then an etching gas is introduced into between the lower and upper electrodes 22 and 23. A high-frequency electric power is applied to each of the lower and upper electrodes 22 and 23 to generate a plasma 27 (plasma discharge) between the lower and upper electrodes 22 and 23, thereby attaining dry etching.

The state illustrated in FIG. 1B is a state of the BARC film 7 and others after the dry etching apparatus illustrated in FIG. 7 is used to etch the BARC film 7 and TEOS film 6. As described above, the etching gas for the TEOS film 6 includes CF₄ gas; thus, side etch is easily generated when the TEOS film 6 is etched. As a result, the aperture dimension (b) of a trench pattern of the TEOS film 6 which is formed by the etching becomes larger than that (a) of a trench pattern formed in the photoresist film 8 (a<b), so that the resultant semiconductor product is unfavorably decreased in short circuit margin between its interconnects.

When the short circuit margin is decreased between the interconnects, it is feared that the reliability of the semiconductor product is affected. Moreover, if a short circuit between the interconnects is caused in the process of producing the semiconductor product, the product becomes a defective product. Consequently, such products are lowered in production yield.

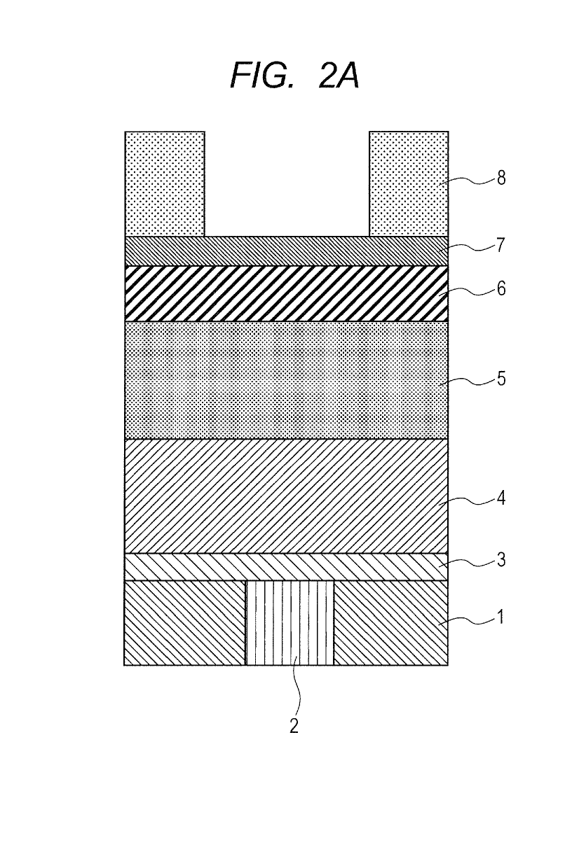

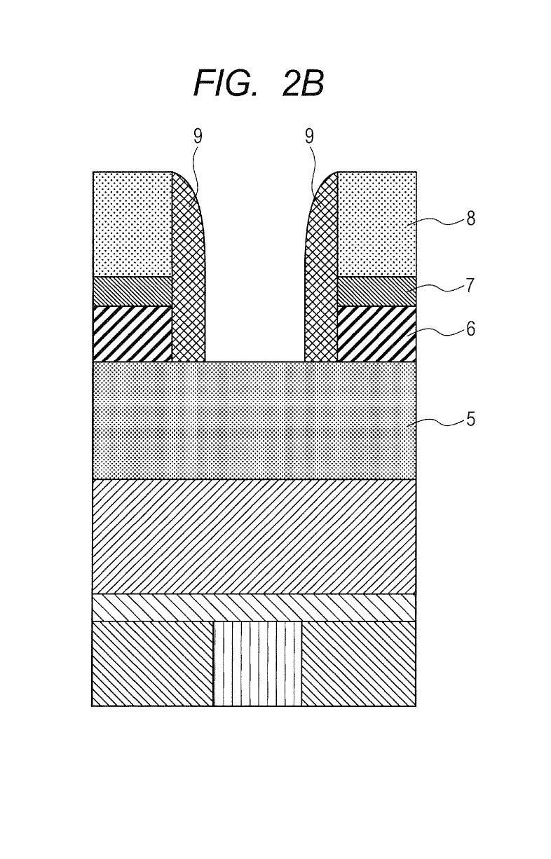

In the present embodiment, therefore, in a trench (interconnect trench) working by use of a multilayered resist, the dry etching apparatus illustrated in FIG. 7 is used to etch a TEOS film 6 of a stacked film structure illustrated in FIG. 2A under dry etching conditions shown in Table 1 to attain the etching while a deposition (reaction product) film 9 is formed on side walls of the TEOS film 6, a BARC film 7 and a photoresist film 8 as illustrated in FIG. 2B. In other words, the etching is attained using a mixed gas including, as components thereof, at least CF₄ gas and C₃H₂F₄ gas instead of the Ar/CF₄ mixed gas, so that the TEOS film 6 can be worked with a high precision while the side etch of the TEOS film 6 is restrained.

When the TEOS film 6 is desired to be etched with a higher precision, dry etching conditions shown in Table 2 are used.

TABLE 1

| Parameter | | Set range | Notes |
|---|---|---|---|
| Upper RF electric power (W) | | 200-2000 | 60 MHz |
| Lower RF electric power (W) | | 200-2000 | 2 MHz |
| Processing pressure (Pa) | | 3.99-66.65 | (30-500 mTorr) |
| Etching gas | CF₄ | 100-500 | |
| (sccm) | C₃H₂F₄ | 5-50 | |
| | O₂ | 10-100 | Optional |
| | N₂ | 50-500 | addition of O₂ or |
| | | | N₂ |
| | Ar | 100-500 | Optional |
| | | | addition as |
| | | | carrier gas |

TABLE 2

| | Parameter | | Set range | Notes |
|---|---|---|---|---|
| Upper RF electric power (W) | | | 500-1500 | 60 MHz |
| Lower RF electric power (W) | | | 500-1500 | 2 MHz |
| Processing pressure (Pa) | | | 3.99-26.65 | (30-200 mTorr) |
| | Etching gas | CF₄ | 100-250 | |
| | (sccm) | C₃H₂F₄ | 5-25 | |
| | | O₂ | 10-50 | Optional |
| | | N₂ | 50-100 | addition of O₂ or |
| | | | | N₂ |
| | | Ar | 100-250 | Optional |
| | | | | addition as |
| | | | | carrier gas |

As described above, in the drying etching in the present embodiment, a mixed gas including, as components thereof, at least tetrafluoromethane (CF₄) and C₃H₂F₄ is used as shown in Tables 1 and 2.

As this gas C₃H₂F₄, a gas of a molecule having a linear or cyclic structure and represented by any one of chemical formulae 1 to 8 illustrated below is used.

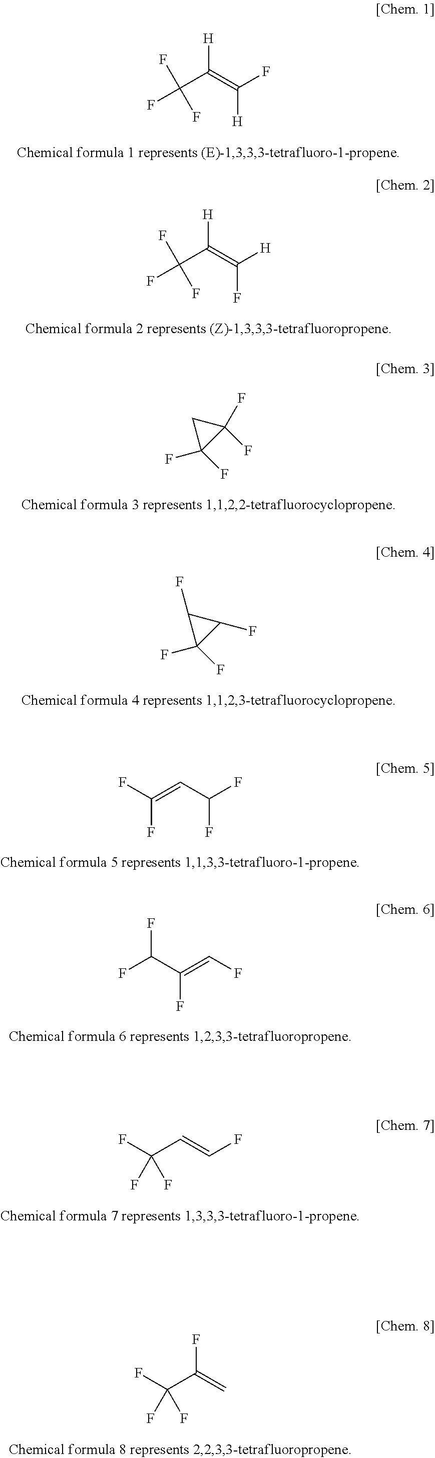

The molecule of C₃H₂F₄ may be in any form that the number of carbon atoms (C) is 3, that of hydrogen atoms (H) is 2 and that of fluorine atoms (F) is 4; thus, the molecule may be a C₃H₂F₄ molecule in which any one of the hydrogen atoms and the fluorine atoms is bonded to a carbon atom through an a bond or 13 bond, or a C₃H₂F₄ molecule in which any one of the hydrogen atoms and the fluorine atoms is added to a carbon atom through one or more radicals.

The individual forms of the C₃H₂F₄ molecule that have been illustrated or described above are different from each other in the dissociation degree of the molecule in accordance with the linear structure or cyclic structure thereof, and with whether or not some of the carbon atoms have a double bond. It is therefore preferred to select the molecule of C₃H₂F₄ to make a target to be etched into a desired etching shape, and use the selected molecule.

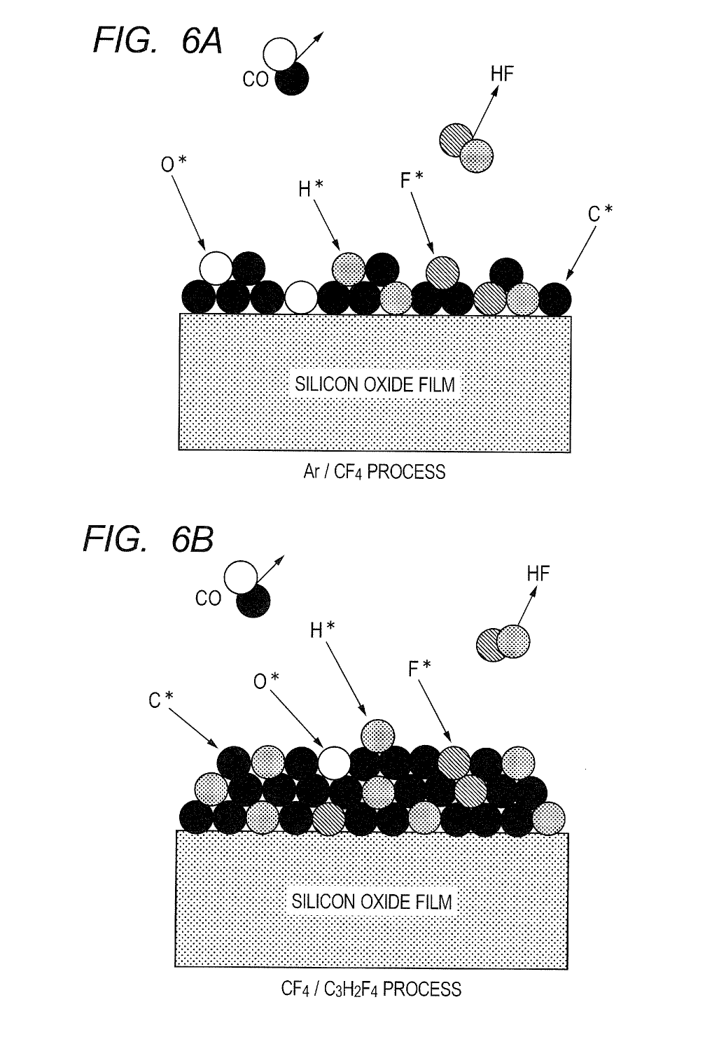

Referring to FIGS. 6A and 6B, the following will describe a reason why as has been illustrated in FIG. 2B, when the TEOS film 6, which is an intermediate layer as one of the constituents of the multilayered resist, is etched, the deposition (reaction product) film 9 is efficiently formed on the side walls of the etched TEOS film 6 by using the mixed gas of tetrafluoromethane (CF₄) and C₃H₂F₄.

FIGS. 6A and 6B are each a view that schematically illustrates a reaction of a surface of a TEOS film (silicon oxide film) while the film is dry-etched. FIG. 6A is a situation of the reaction while the drying etching is performed with a conventional mixed gas of Ar and CF₄, and FIG. 6B is a situation of the reaction while the drying etching is performed with a mixed gas of CF₄ and C₃H₂F₄. In each of the figures, each symbol “*” represents a radical, i.e., an atom or molecule having an unpaired electron.

Each of gas molecules that constitute an etching gas is dissociated in a plasma to produce an ion or radical. As well as the TEOS film 6, the photoresist film 8 and the BARC film 7 are also etched, so that also from materials of these films, oxygen radicals (O*) and hydrogen radicals (H*) are supplied into the plasma. The radicals in the plasma are partially bonded to each other to produce carbon monooxide (CO), hydrogen fluoride (HF), and others. These produced compounds are subjected to vacuum-evacuation.

The radicals also partially adhere onto the outer surface of the TEOS film to produce a polymer (deposition) film. This polymer (deposition) film functions as a protecting film for protecting etching-side-wall-surfaces of the TEOS film from undergoing sputtering by ions generated in the plasma, and a chemical reaction between fluorine radicals (F*) and the TEOS film outer surface.

As illustrated in FIG. 6B, under the dry etching conditions when the CF₄/C₃H₂F₄ mixed gas is used for the dry etching, the polymer (deposition) film is formed more thickly than under the conventional etching conditions illustrated in FIG. 6A. This is because the use of C₃H₂F₄ as one of the components of the etching gas makes an increase in the number of the carbon (C) and hydrogen (H) atoms supplied into the plasma. As a result, the TEOS film can be heightened in etching resistance to be decreased in side etch quantity.

In the CF₄/C₃H₂F₄ mixed gas used for the dry etching, CF₄ gas is a main etching gas, which contributes mainly to the etching of the silicon oxide film. About the CF₄/C₃H₂F₄ mixed gas, the flow rate of CF₄ needs to be smaller than that of C₃H₂F₄. As described above, C₃H₂F₄ gas contributes to the formation of the polymer (deposition) film; thus, if the flow rate of C₃H₂F₄ is larger than that of CF₄, the quantity of the formed polymer (deposition) film is too large so that the etching of the TEOS film 6 is unfavorably disturbed. For example, on the way of the etching, the etching of the TEOS film 6 may be unfavorably stopped (etch stop).

As shown in Table 1 or 2, argon (Ar) gas may be optionally added as a diluting gas (carrier gas) to the etching gas. By the addition of Ar gas, Ar ions are produced in the plasma, so that when the TEOS film 6 is etched, an ion assist etching effect can be obtained for the etching trench bottom.

Oxygen (O₂) gas or nitrogen gas (N₂) may be optionally added to the etching gas. The addition of oxygen (O₂) gas or nitrogen gas (N₂) makes it possible to adjust an etching shape (trench shape) formed by the dry etching. In the addition of O₂, it is more preferred to set the respective flow rates of gases in a CF₄/C₃H₂F₄/O₂ mixed gas as follows: the flow rate of CF₄>that of O₂>that of C₃H₂F₄. In the addition of N₂, it is more preferred to set the respective flow rates of gases in a CF₄/C₃H₂F₄/N₂ mixed gas as follows: the flow rate of CF₄>that of N₂>that of C₃H₂F₄.

If the flow rate of C₃H₂F₄ is too large in any one of the O₂ addition and N₂ addition cases, it becomes difficult to control the etching-shape (trench-shape) by the O₂ addition or N₂ addition. In other words, it is preferred to make C₃H₂F₄ gas smaller in flow rate than each of CF₄ and Ar gas, and also make C₃H₂F₄ gas equivalent in flow rate to or smaller therein than each of oxygen (O₂) gas and nitrogen gas (N₂).

In particular, when an insulating film such as an oxide film is etched, it is preferred to add oxygen (O₂) gas to the etching gas. In the case of using a carbon-added silicon oxide film (SiOC film), or any other organic insulating film lower in dielectric constant than silicon oxide films, it is preferred to use, as an etching gas therefor, a CF₄/C₃H₂F₄/N₂ mixed gas. This case makes it possible to prevent the side etch of the organic insulating film.

As described above, according to the semiconductor device producing method in the present embodiment, at the time of dry-etching a TEOS film, which is an intermediate layer in a single damascene process using a multilayered resist, the side etch of the TEOS film can be restrained, so that the intermediate layer (TEOS film) can be worked with a higher precision.

This matter makes it possible in a subsequently-performed etching of a lower-layer resist film 5 and a silicon oxide film 4 in FIG. 2B to attain the etching with a higher precision to prevent the resultant semiconductor device from being decreased in short circuit margin between its interconnects.

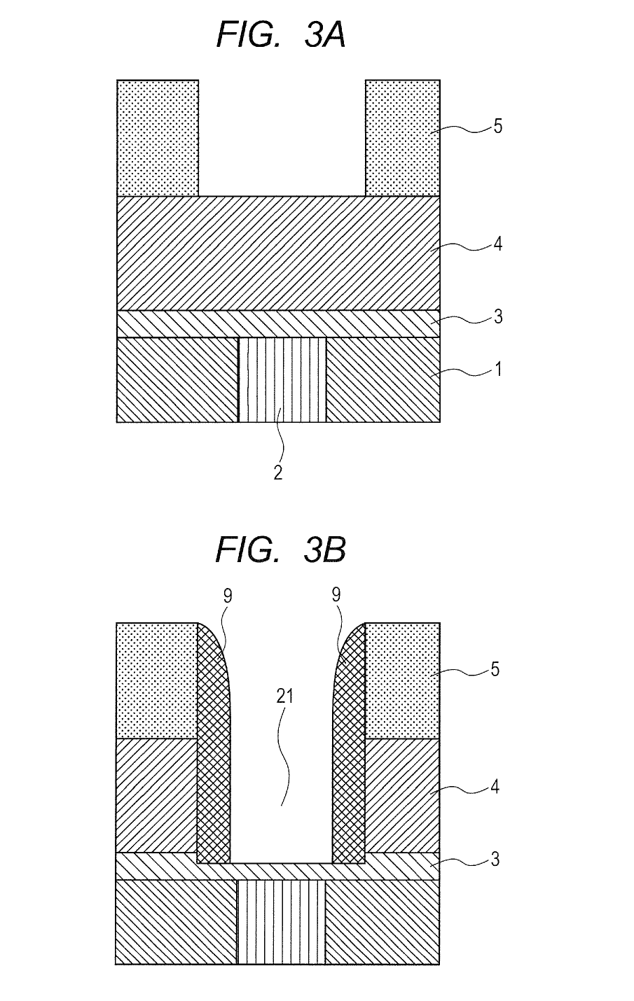

FIG. 3A illustrates a state that a trench (interconnect trench) pattern is formed in the lower-layer resist film 5 on the silicon oxide film 4. When the dry etching apparatus illustrated in FIG. 7 is used to etch the stacked film structure illustrated in FIG. 3A under the conditions shown in Table 1 or 2, the silicon oxide film 4 can be etched while a deposition (reaction product) film 9 can be formed on etching-side-walls of the silicon oxide film 4 as illustrated in FIG. 3B. Consequently, the side etch of the etching-side-walls of the silicon oxide film 4 can be restrained.

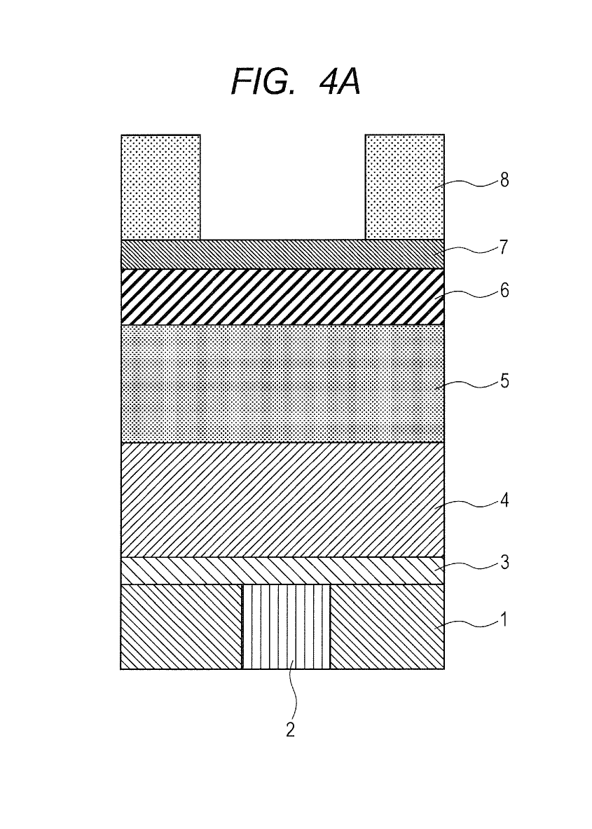

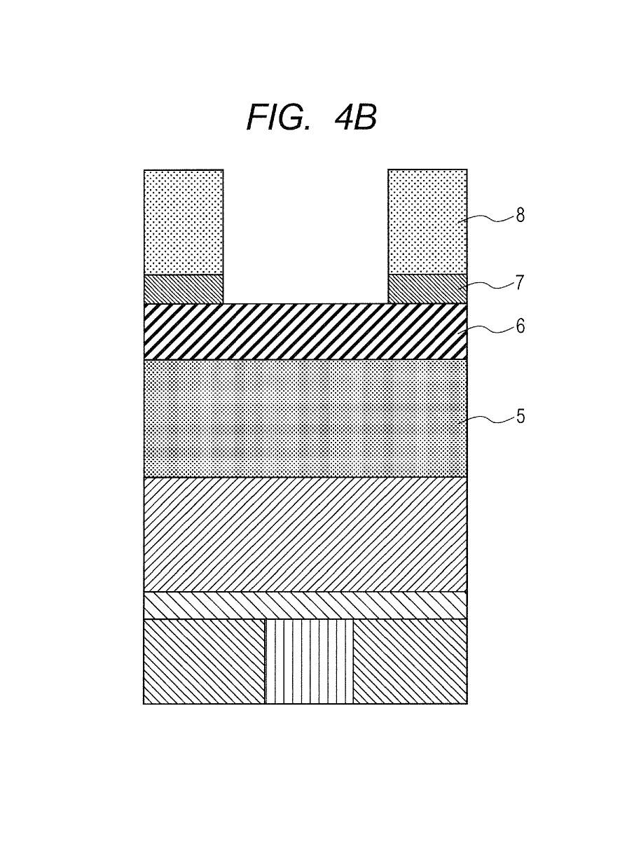

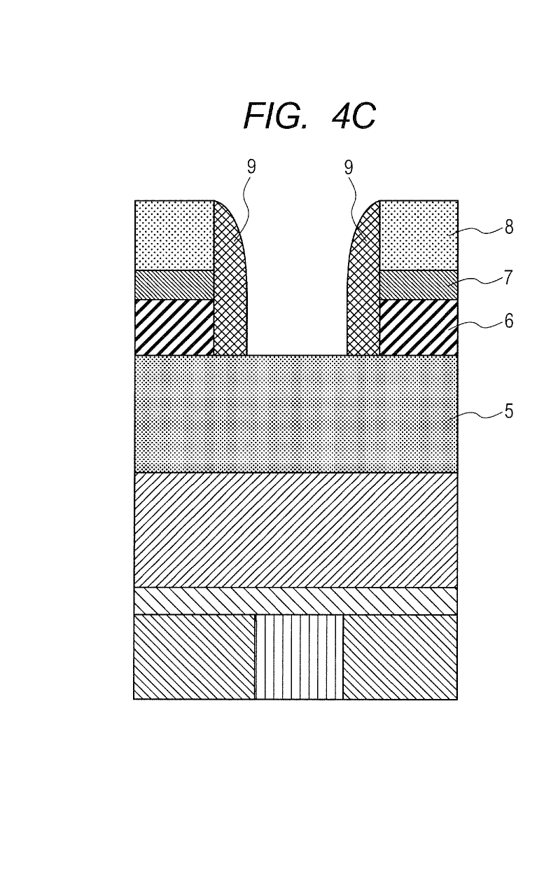

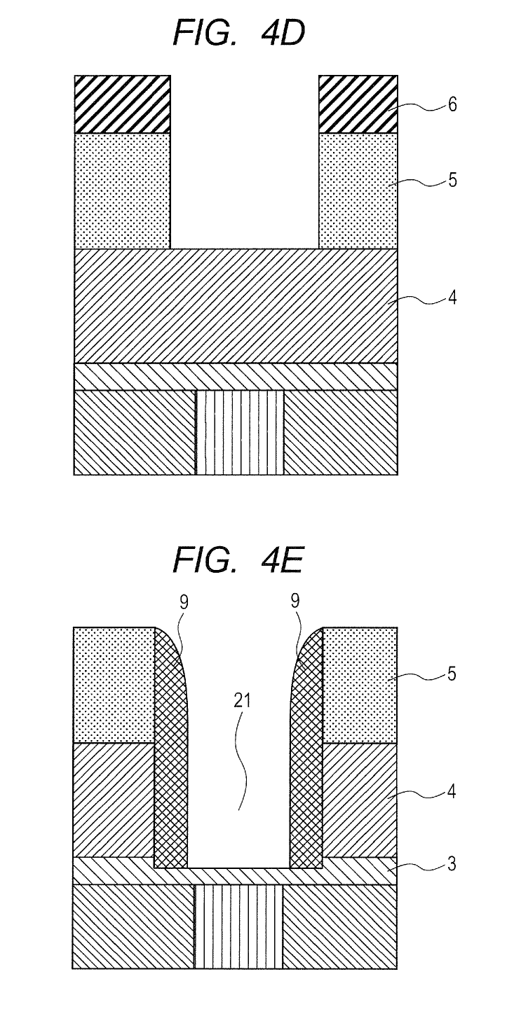

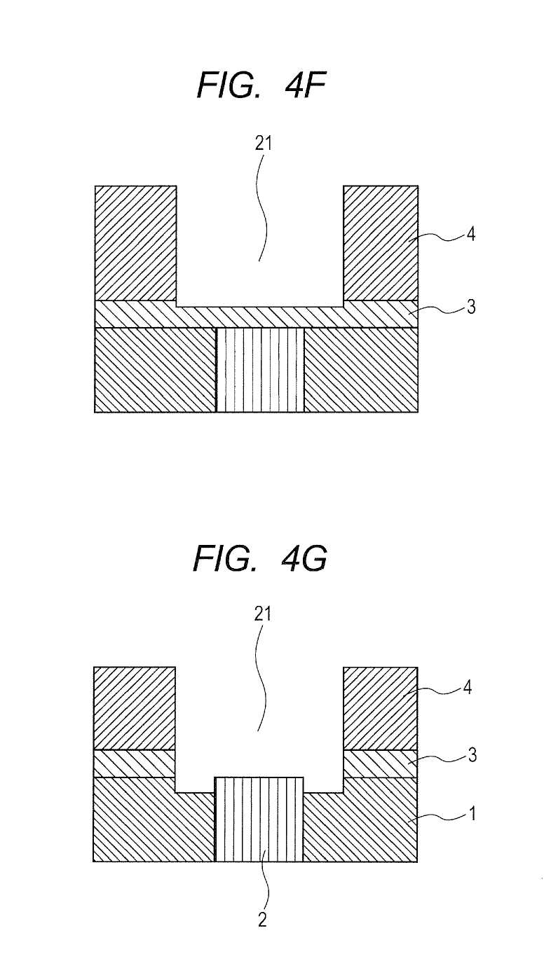

Referring to FIGS. 4A to 4G, the following will describe a series of steps of working trenches (interconnect trenches) in a single damascene process as described above.

As illustrated in FIGS. 4A and 4B, a photoresist film 8 is used as a mask to etch a BARC film 7. For this etching, tetrafluoromethane (CF₄) gas is used. At this time, the photoresist film 8 is also etched to be decreased in film thickness.

Next, as illustrated in FIGS. 4B and 4C, the photoresist film 8 and the patterned BARC film 7 are used as a mask to etch a TEOS film 6 which is an intermediate layer of a multilayered resist. For this etching, a CF₄/C₃H₂F₄ mixed gas is used as shown in Table 1 or 2. A different mixed gas is usable in which one or more of O₂ gas, N₂ gas and Ar gas are further added to a CF₄/C₃H₂F₄ mixed gas as required. At this time, the photoresist film 8 is also etched to be further decreased in film thickness.

Since the etching gas includes C₃H₂F₄ gas, a deposition (reaction product) film 9 is formed as a side wall protecting film on side walls of the TEOS film 6, the BARC film 7 and the photoresist film 8 to restrain the side etch of these films. When O₂ gas is added to the etching gas in this step, it is desired to make the addition amount of O₂ gas smaller in the step than in a silicon-oxide-film-4-etching step that will be detailed later.

Subsequently, as illustrated in FIGS. 4C and 4D, in the state that the deposition film 9 is formed on the side walls of the photoresist film 8, and the BARC film 7 and TEOS film 6, the photoresist film 8 and the deposition film 9 are used as a mask to etch the lower-layer resist film 5. For this etching, a N₂/O₂ mixed gas or a N₂/O₂/CH2F2 mixed gas is used. At this time, the photoresist film 8 and the BARC film 7 are also etched so that the pattern TEOS film 6 and the lower-layer resist film 5 remain on the silicon oxide film 4. At this time, the deposition film 9 is also removed.

Thereafter, as illustrated in FIGS. 4D and 4E, the patterned TEOS film 6 and lower-layer resist film 5 are used as a mask to etch the silicon oxide film 4. For this etching, a CF₄/C₃H₂F₄ mixed gas is used, or a different mixed gas is usable in which one or more of O₂ gas, N₂ gas and Ar gas are further added to a CF₄/C₃H₂F₄ mixed gas as required.

At this time, the etching gas includes C₃H₂F₄ gas; thus, a deposition (reaction product) film 9 is formed as a side wall protecting film on side walls of the silicon oxide film 4 and the lower-layer resist film 5 to restrain the side etch of these films. Moreover, the TEOS film 6 is removed while the silicon oxide film 4 is etched. When O₂ gas is added to the etching gas in this step, it is desired to make the addition amount of O₂ gas larger in the step than in the above-mentioned step of etching the TEOS film 6.

Furthermore, as illustrated in FIGS. 4E and 4F, the workpiece is subjected to asking with oxygen (O₂) gas to remove the lower-layer resist film 5 and the deposition (reaction product) film 9.

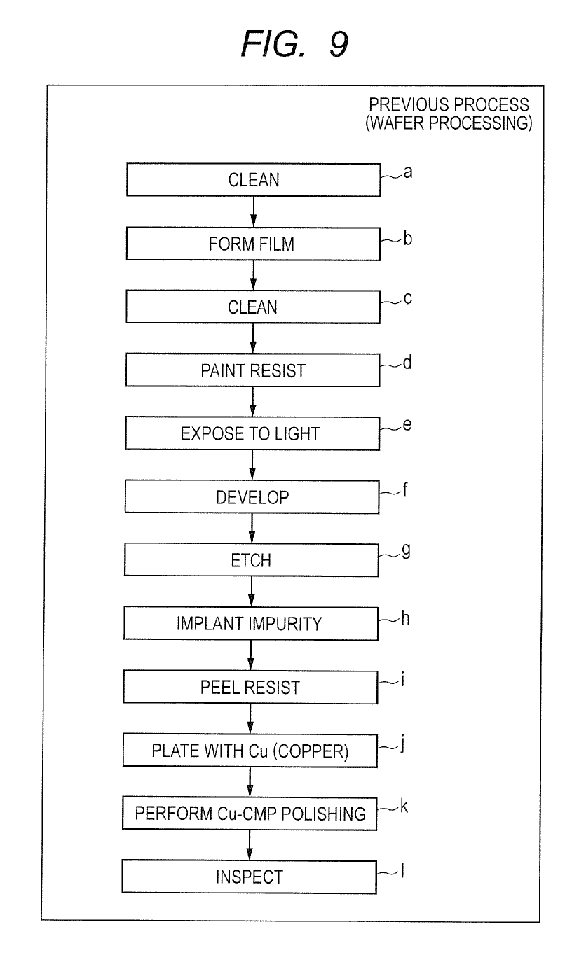

Lastly, as illustrated in FIGS. 4F and 4G, the barrier film (SiCN film) 3 is etched with an Ar/CF₄/O₂ mixed gas. In this way, the W plugs including the W plug 2 and the lower-layer interconnects not illustrated are made naked to end the present process. In the made trenches (interconnect trenches) including the trench 21, buried copper interconnects are formed through a subsequent Cu (copper) plating step and CMP (chemical-mechanical-polishing) step (Step j and Step k in FIG. 9).

As described above, when the trenches (interconnect trenches) including the trench 21 are made in the silicon oxide film 4 through the single damascene process illustrated in FIGS. 4A to 4G, the etch gas including the CF₄/C₃H₂F₄ mixed gas is used to etch the TEOS film 6, which is the intermediate layer of the multilayered resist, and the silicon oxide film 4, which is the working-receiving film. This manner makes it possible to make the trenches (interconnect trenches) with a good precision to prevent the resultant semiconductor device from being decreased in short circuit margin between the interconnects.

### Second Embodiment

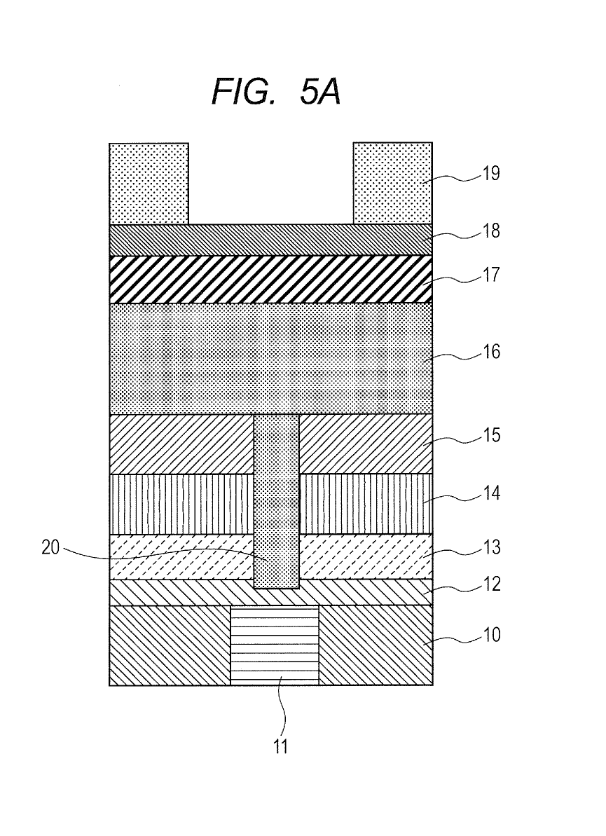

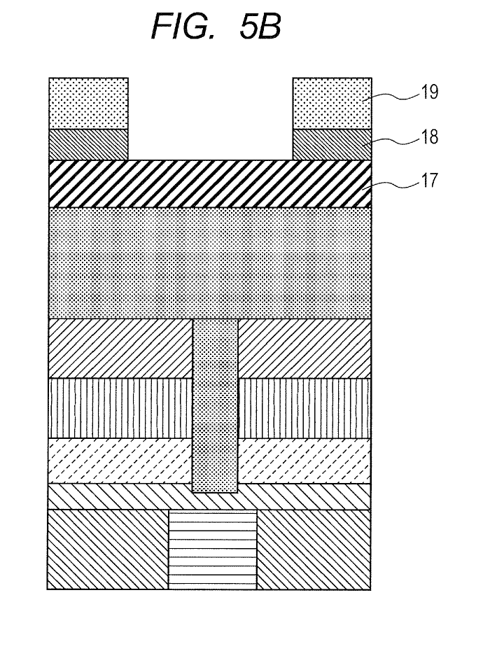

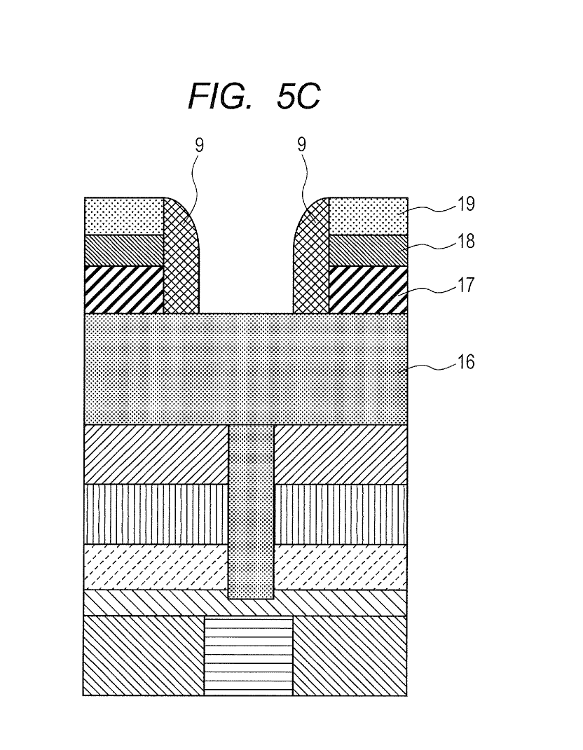

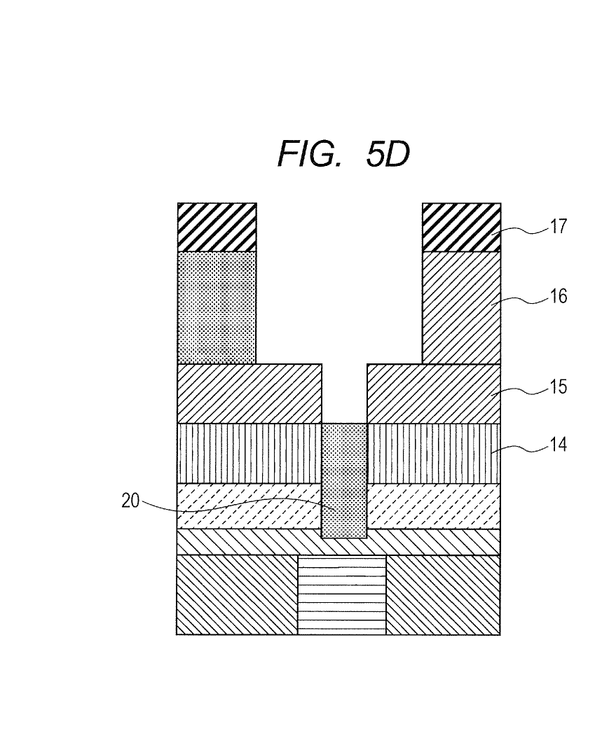

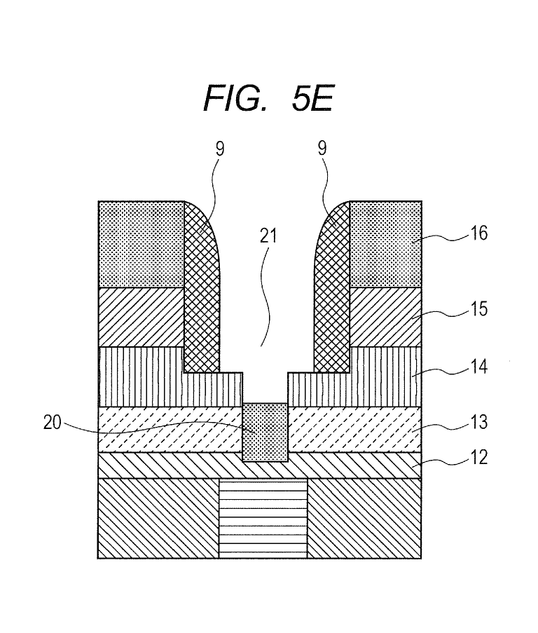

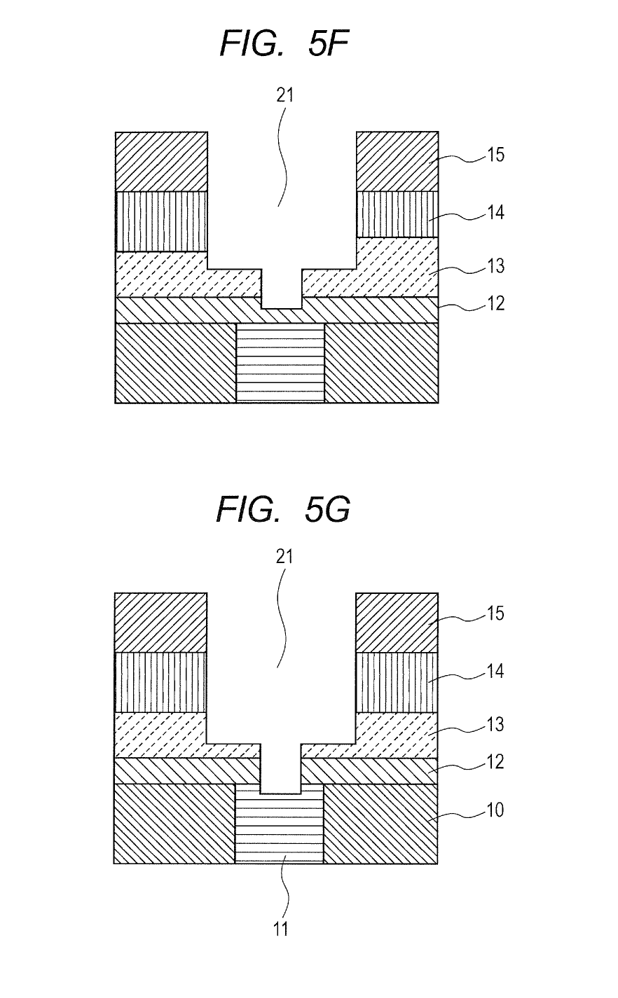

Referring to FIGS. 5A to 5G, the following will describe a trench (interconnect trench) working method in a dual damascene process in Second Embodiment.

FIG. 5A illustrates a state of a stacked film structure in which two different interlayer dielectrics are formed over a surface of a semiconductor wafer, and a multilayered resist made of four layers is formed over the interlayer dielectrics before the structure is etched. FIG. 5B illustrates a state thereof after a BARC film and a TEOS film, which constitute parts of the multilayered resist film after the etching. Cu interconnects including a Cu interconnect 11 are formed in portions of one 10 of the two interlayer dielectrics. The interlayer dielectric 10 is, for example, an organic insulating film such as a carbon-added silicon oxide film (SiCO film), and has a lower dielectric constant than silicon oxide films. A barrier film (SiCN film) 12 is formed on the interlayer dielectric 10.

On the barrier film (SiCN film) 12, the other interlayer dielectric, which has trilayered structure, is formed; and the interlayer dielectric is a working-receiving film in which trenches (interconnect trenches) are to be made. This trilayered interlayer dielectric has, in turn from the lower thereof, a low-dielectric-constant film A13, a low-dielectric-constant film B14, and a silicon oxide film 15. The low-dielectric-constant film A13 and the low-dielectric-constant film B14 are organic or inorganic low-dielectric-constant films different from each other in raw material, and each have a lower dielectric constant than silicon oxide films. The order that these films are stacked onto each other may be appropriately changed in accordance with a required dielectric constant of the interlayer dielectric.

The state illustrated in FIG. 5A is a state that via holes including an illustrated via hole are made. The via holes are made by dry-etching the low-dielectric-constant film A13, the low-dielectric-constant film B14 and the silicon oxide film 15 with a CF₄/C₃H₂F₄ mixed gas. At this time, CF₄/C₃H₂F₄ mixed gas conditions are the same as shown in Table 1 or 2.

In the same manner as in First Embodiment, on the trilayered interlayer dielectric, the above-mentioned multilayered resist, which has four layers, is formed. As illustrated in FIG. 5A, this multilayered resist, which has the four layers, has, in turn from the lower thereof, a lower-layer resist film 16, the TEOS film referred to above, which is an intermediate layer 17, the BARC film referred to above, which functions as a bottom-anti-reflection-coating film 18 when the workpiece is exposed to light, and a photoresist film 19. The TEOS film 17 is an example of an insulating film, and may be a film of a different raw material.

The photoresist film 19 is an ArF resist photosensitized by ArF exposure using an ArF laser. In the photoresist film 19, a predetermined pattern for, for example, an interconnect pattern or circuit pattern of a semiconductor device is formed through a photolithography using an ArF exposure apparatus.

Via fills including a via fill 20 are beforehand formed in the trilayered interlayer dielectric, that is, the low-dielectric-constant film A13, the low-dielectric-constant film B14 and the silicon oxide film 15. The formation of the via fills including the via fill 20 is attained by making the via holes (contact holes) in the trilayered interlayer dielectric by dry etching, and then filling the holes with a via fill material.

The process from the step illustrated in FIG. 5A to that illustrated in FIG. 5G is performed under dry etching conditions shown in Table 3, using a dry etching apparatus as has been shown in FIG. 7 in the same manner as in First Embodiment. In the same manner as in First Embodiment, one or more of O₂ gas, N₂ gas and Ar gas may be appropriately added to the CF₄/C₃H₂F₄ mixed gas as required in accordance with a raw material of each of the insulating films to be etched.

In Table 3, Step 1 shows conditions for the step of etching the BARC film 18; Step 2, conditions for the step of etching the TEOS film 17, which is the intermediate layer 17; Step 3, conditions for the step of etching the low-layer resist 16; Step 4, conditions for the step of etching the silicon oxide film 15 and the low-dielectric-constant film B14 partially; and Step 5, conditions for the step of etching the barrier film 12.

TABLE 3

| | | step | | | | | |
|---|---|---|---|---|---|---|---|
| | | | 2 | 3 | | | |
| | | 1 | Immediate | Lower | 4 | 5 | |
| | | BARC | layer | layer | SiO/ | SiCN | |
| parameter | | etching | etching | etching | SiOC | removal | Notes |
| Upper RF electric | | 200-2000 | 500 | 200-2000 | 500 | 200-2000 | 60 MHz |
| power (W) | | | | | | | |
| Lower RF electric | | 200-2000 | 500 | 200-2000 | 500 | 200-2000 | 2 MHz |
| power (W) | | | | | | | |
| Processing | (Pa) | 3.99-26.65 | 3.99-26.65 | 1.33-26.65 | 3.99-26.65 | 3.99-26.65 | |
| pressure | | | | | | | |
| | (mTorr) | 30-200 | 30-200 | 10-200 | 30-200 | 30-200 | |
| Etching gas | CF₄ | 50-500 | 100-250 | — | 100-250 | 50-500 | |
| (sccm) | C₄F₈ | 0-20 | — | — | — | — | |
| | C₃H₂H₄ | — | 5-50 | — | 5-50 | — | |
| | O₂ | | | | | — | Optional |
| | N₂ | | | | | — | addition of |
| | | | | | | | O₂ or N₂ |
| | | | | | | | in each of |
| | | | | | | | steps 2 and 4 |
| | Ar | 0-1000 | 100-500 | | 100-500 | 0-1000 | Optional |
| | | | | | | | addition as |
| | | | | | | | carrier gas |
| | | | | | | | in each of |
| | | | | | | | steps 2 and 4 |

Initially, as illustrated in FIGS. 5A and 5B, the photoresist film 19 is used as a mask to etch the BARC film 18. For this dry etching, a CF₄/O₂ mixed gas is used (Step 1 in Table 3). At this time, photoresist film 19 is also etched to be decreased in film thickness.

Next, as illustrated in FIGS. 5B and 5C, the photoresist film 19 and the patterned BARC film 18 are used as a mask to dry-etch the TEOS film 17. For this dry etching, a CF₄/C₃H₂F₄/O₂ mixed gas or a CF₄/C₃H₂F₄/N₂ mixed gas is used (Step 2 in Table 3). At this time, a deposition (reaction product) film 9 is formed on side walls of the TEOS film 17, the BARC film 18, and the photoresist film 19 to prevent the side etch of these films. Moreover, the photoresist film 19, together with the TEOS film 17, is etched to be further decreased in film thickness. When O₂ gas is added to the etching gas in this step, it is desired to make the addition amount of O₂ gas smaller in the step than in a silicon-oxide-film-15-etching step that will be detailed later.

Subsequently, as illustrated in FIGS. 5C and 5D, in the state that the deposition film. 9 is formed on the side walls of the photoresist film 19, and the patterned BARC film 18 and TEOS film 17, the photoresist film 19 and the deposition film 9 are used as a mask to dry-etch the lower-layer resist film 16. For this dry etching, a N₂/O₂ mixed gas or a mixed gas in which CH2F2 is added to a N₂/O₂ mixed gas is used (Step 3 in Table 3). At this time, the low-layer resist 16, together with the photoresist film 19 and the BARC film 18 above the resist 16, is etched and removed. At this time, the deposition film 9 is also removed.

Thereafter, as illustrated in FIGS. 5D and 5E, the patterned TEOS film 17 and lower-layer resist film 16 are used as a mask to dry-etch the silicon oxide film 15 and the low-dielectric-constant film B14, which constitute parts of the trilayered interlayer dielectric, partially. For this dry etching, a CF₄/C₃H₂F₄/O₂ mixed gas or a CF₄/C₃H₂F₄/N₂ mixed gas is used (Step 4 in Table 3). At this time, a deposition (reaction product) film 9 is formed on side walls of the low-dielectric-constant film B14, the silicon oxide film 15 and the low-layer resist 16, so that the side etch of these films can be prevented.

The use of, in particular, the CF₄/C₃H₂F₄/N₂ mixed gas makes it possible to restrain the side etch of the low-dielectric-constant film B14 more effectively. When the silicon oxide film 15 is etched, it is preferred to use the CF₄/C₃H₂F₄/O₂ mixed gas. In this case, the addition amount of O₂ gas is desirably made smaller than in the above-mentioned step of etching the TEOS film 17. Moreover, as described above, when the low-dielectric-constant film. B14 is etched, it is preferred to use the CF₄/C₃H₂F₄/N₂ mixed gas.

Furthermore, as illustrated in FIGS. 5E and 5F, the workpiece is subjected to asking with O₂ to remove the lower-layer resist 16, the deposition (reaction product) film. 9, the low-dielectric-constant film B14 and the low-dielectric-constant film A13 partially, and remove the via fills 20.

Lastly, as illustrated in FIGS. 5F and 5G, the barrier film 12 at the bottom of the via holes is dry-etched to be removed. In this way, the via holes are made for forming contacts (vias) between the trenches (interconnect trenches) including the trenches including the trench 21 and the interconnects including the interconnect 11 below the trenches (Step 5 in Table 3).

As described above, the semiconductor device producing method in the present embodiment makes the following possible in a dual damascene process: when trenches (interconnect trenches) are made in an interlayer dielectric of a stacked structure including low-dielectric-constant films, such as a silicon oxide film and a carbon-added silicon oxide film (SiCO film), side etch is effectively restrained. Thus, with a higher precision, trench (interconnect trench) working can be attained.

In the present embodiment, disclosed is an example including the low-dielectric-constant film A13, the low-dielectric-constant film B14 and the silicon oxide film 15 as films of an interlayer dielectric. However, the present invention is not limited to this example. Thus, the interlayer dielectric may be a bilayered film of the low-dielectric-constant film A13 and the low-dielectric-constant film B14, or may be a monolayered film.

### Third Embodiment

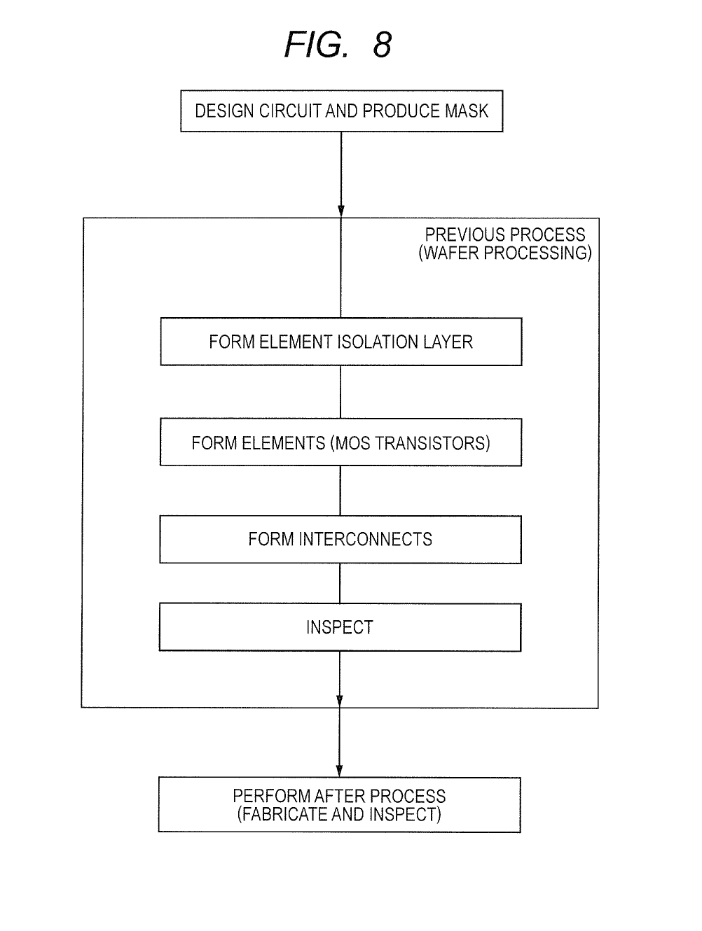

Referring to FIGS. 8 and 9, the following will describe a method for producing a semiconductor device, such as an advanced microcomputer, an advanced SOC product or a highly functional liquid crystal driver, through a process flow as described in First Embodiment or Second Embodiment. FIG. 8 is a flow chart showing an outline of a process for producing the semiconductor device. FIG. 9 is a flow chart showing an outline of a pre-process for this semiconductor device producing process.

As shown in FIG. 8, the semiconductor device producing process is roughly classified into three steps.

Initially, a semiconductor circuit is designed, and on the basis of the circuit design, a mask is produced.

Next, in a wafer processing process called a previous process, a surface treatment that may be of various types is repeatedly applied plural times to a surface of a substrate of a semiconductor such as silicon to form integrated circuits. As illustrated in FIG. 8, this previous process is roughly classified to a step of forming an element isolation layer, a step of forming elements such as MOS transistors, an interconnect-forming step of forming interconnects between the individual elements and transistors, a step of inspecting the finished wafer, and other steps.

Furthermore, in an after process, the wafer having the surface on which the integrates circuits are formed is separated into individual units. The units are each fabricated into a semiconductor device, and then the device is inspected.

In the previous process, which is the wafer processing process, surface processing steps, i.e., Steps “a” to “i” shown in FIG. 9 are repeated plural times.

Initially, surfaces of a wafer which is a semiconductor substrate are cleaned to remove alien matters and impurities adhering to the wafer surfaces (Step “a”).

Next, for example, a CVD apparatus is used to form thin films on/over one of the wafer surfaces. The thin films are, for example, interlayer dielectrics, such as a silicon oxide film and a low-dielectric-constant film, and a film in which interconnects are to be made, such as an aluminum film (Step “b”).

After the formation of the thin films on/over the wafer surface, the workpiece is again cleaned to remove alien matters and impurities adhering to the surfaces of the workpiece (Step “c”).

A resist material such as a photosensitive material is painted onto the wafer having the surface, on/over which the interlayer dielectrics and the film in which the interconnects are to be made are formed (Step “d”).

A mask in which a desired circuit pattern is formed is used to transfer the circuit pattern onto the resist by means of an exposure apparatus such as an ArF exposure apparatus (Step “e”).

The workpiece is subjected to developing treatment to remove unnecessary portions of the resist to shape the desired circuit pattern in the resist over the wafer (Step “f”).

The resist, in which the desired circuit pattern is shaped, is used as an etching mask to etch and remove unnecessary portions of the thin films formed on/over the wafer by means of a dry etching apparatus. In this way, the desired circuit pattern is finished in the thin films (Step “g”). This step corresponds to the formation of the trenches (interconnect trenches) in First Embodiment or Second Embodiment.

Thereafter, as required, an ion implanting apparatus is used to implant impurities onto the wafer surface (Step “h”).

The resist formed over the wafer is peeled (removed) by asking processing or cleaning (Step “i”).

When a single damascene process or dual damascene process is used to form buried copper interconnects, a plating processing is used to bury copper (Cu) into the trenches (interconnect trenches) and the via holes made in the thin films by the etching in Step g (Step j).

An excess of copper (Cu) that is produced on the wafer surface is removed by Cu-CMP polishing (step k).

Lastly, an alien matter inspecting apparatus and an external appearance inspecting apparatus are used to inspect whether or not an alien matter is present on the wafer, and whether or not the desired circuit pattern is precisely formed (Step “l”)

Between any adjacent two of Steps “a” to “l”, for example, a processing of cleaning or drying the wafer is performed as required.

In the semiconductor device producing method in the present embodiment, the single damascene process or the dual damascene process described in First Embodiment or Second Embodiment is applied to the above-mentioned step Step g to form the buried copper interconnects. Specifically, in the dry etching in Step G, a mixed gas containing CF₄ and C₃H₂F₄ is used as an etching gas to attain the etching of the silicon oxide film, which is the intermediate layer out of the layers of the multilayered resist, or etching for making the trenches (interconnect trenches). Buried copper interconnects are formed in the made trenches (interconnect trenches) and via holes by the Cu (copper) plating processing in Step j and Cu-CMP polishing in Step k.

As described above, by applying the process flow described in First Embodiment or Second Embodiment to a process for producing an advanced microcomputer, an advanced SOC product or any other semiconductor device, trenches (interconnect trenches) can be made with a good precision. Thus, such advanced microcomputers, advanced SOC products or semiconductor products can be improved in production yield, and process yield.

The above has specifically described the invention made by the inventors by way of embodiments thereof. However, the present invention is not limited to the embodiments. The embodiments may each be variously changed as far as the changed embodiment does not depart from the subject matter of the invention.

What is claimed is:

1. A method for producing a semiconductor device, comprising the steps of:
(a) forming a working-receiving film over a main surface of a semiconductor wafer;
(b) forming a first resist film over the working-receiving film to cover the working-receiving film;
(c) forming a first insulating film over the first resist film to cover the first resist film;
(d) forming a second resist film over the first insulating film to cover the first insulating film;
(e) transferring a predetermined pattern to the second resist film through a photolithography, and
(f) applying a first dry etching processing after the step (e) to the first insulating film, using a mixed gas comprising, as components thereof, at least CF₄ gas, C₃H₂F₄ gas and O₂ gas.

2. The method for producing a semiconductor device according to claim 1,
wherein about the mixed gas used for the first dry etching processing in the step (f), the flow rate of CF₄>that of C₃H₂F₄ gas.

3. The method for producing a semiconductor device according to claim 1,
wherein the first insulating film is a silicon oxide film, and
wherein about the mixed gas used for the first dry etching processing in the step (f), the flow rate of CF₄>that of C₃H₂F₄ gas.

4. The method for producing a semiconductor device according to claim 1,
wherein the mixed gas used for the first dry etching processing in the step (f) further comprises Ar gas.

5. The method for producing a semiconductor device according to claim 1,
wherein in the step (e), the photolithography is ArF exposure using an ArF laser, and
wherein the second resist film is an ArF resist film.

6. The method for producing a semiconductor device according to claim 1, further comprising the steps of:
(g) removing the second resist film after the step (f);
(h) using the first insulating film as a mask after the step (g) to work the first resist film, and
(i) using the first resist film as a mask after the step (h) to apply a second dry etching processing to the working-receiving film.

7. The method for producing a semiconductor device according to claim 6,
wherein the working-receiving film is a stacked film comprising a layer comprising a silicon oxide film, and
wherein when the silicon oxide film is etched, the second dry etching processing is performed, using a mixed gas comprising, as components thereof, at least CF₄ gas, C₃H₂F₄ gas and O₂ gas.

8. The method for producing a semiconductor device according to claim 7,
wherein the working-receiving film is etched, thereby making, in the working-receiving film, an interconnect trench into which a copper interconnect is to be formed.

9. The method for producing a semiconductor device according to claim 7,
wherein when the silicon oxide film is etched, about the mixed gas used for the second dry etching processing the flow rate of CF₄>that of O₂>that of C₃H₂F₄ gas.

10. The method for producing a semiconductor device according to claim 9,
wherein the O₂ gas in the mixed gas used for the first dry etching processing is smaller in flow rate than that in the mixed gas used for the second dry etching processing.

11. The method for producing a semiconductor device according to claim 6,
wherein the working-receiving film comprises a layer comprising a carbon-added silicon oxide film, and
wherein when the carbon-added silicon oxide film is etched, the second dry etching processing is performed, using a mixed gas comprising, as components thereof, at least CF₄ gas, C₃H₂F₄ gas and N₂ gas.

12. The method for producing a semiconductor device according to claim 11,
wherein when the carbon-added silicon oxide film is etched, about the mixed gas used for the second dry etching processing the flow rate of CF₄>that of C₃H₂F₄ gas.

13. The method for producing a semiconductor device according to claim 11,
wherein when the carbon-added silicon oxide film is etched, about the mixed gas used for the second dry etching processing the flow rate of CF₄>that of N₂>that of C₃H₂F₄ gas.

14. The method for producing a semiconductor device according to claim 11,
wherein when the carbon-added silicon oxide film is etched, the mixed gas used for the second dry etching processing further comprises Ar gas.
